(19) United States
(12) Patent Application Publication
(10) Pub. No.: US 2025/0221149 A1
(43) Pub. Date: Jul. 3, 2025

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Mi Na KIM, Paju-si (KR); Yong Cheol KIM, Paju-si (KR)

(73) Assignee: LG Display Co., Ltd., Seoul (KR)

(21) Appl. No.: 18/934,022

(22) Filed: Oct. 31, 2024

(30) Foreign Application Priority Data
Dec. 29, 2023 (KR) 10-2023-0197868

(51) Int. Cl. H10K 50/12; C09K 11/02; C09K 11/06; H10K 50/13; H10K 50/18; H10K 101/00; H10K 101/10; H10K 101/40

(52) U.S. Cl. CPC H10K 50/12; C09K 11/02; C09K 11/06; H10K 50/131; H10K 50/181; H10K 2101/10; H10K 2101/40; H10K 2101/90

(57) ABSTRACT

A light emitting device can include a first electrode and a second electrode facing each other, and an electron blocking layer, a first light emitting layer, and an electron transport layer between the first electrode and the second electrode. The first light emitting layer can include a p-type host, a first n-type host, a second n-type host, and a dopant, a LUMO energy level of the first n-type host is higher than a LUMO energy level of the second n-type host. A hole mobility of the first n-type host can be greater than a hole mobility of the second n-type host and can be smaller than a hole mobility of the p-type host.

### CROSS REFERENCE TO RELATED APPLICATION

This application claims the priority benefit of the Korean Patent Application No. 10-2023-0197868, filed in the Republic of Korea on Dec. 29, 2023, the entire contents of which are hereby incorporated by reference into the present application.

### BACKGROUND

### Field of the Invention

The disclosure relates to a light emitting device, and more particularly, to a light emitting device and a light emitting display device to improve luminous efficacy as well as lifespan.

### Discussion of the Related Art

With the advent of the information society, displays for visually expressing electrical information signals have rapidly developed. In response to this, a variety of display devices with excellent performance such as slimness, low weight, and low power consumption are being developed.

A light emitting display device that does not require a separate light source to realize compactness and clear color and has a light emitting element in a display panel has been considered as a competitive application.

The light emitting element can include an anode and a cathode facing each other as electrodes, a light emitting layer between the anode and the cathode, and a common layer for transferring holes and electrons to the light emitting layer.

Meanwhile, light emitting devices use light emitting materials that emit light with different wavelengths for expressing color, and can have differences in efficiency and lifespan of the light emitting materials depending on wavelength.

### SUMMARY OF THE DISCLOSURE

Accordingly, the disclosure is directed to a light emitting device and a light emitting display device that substantially obviate one or more problems due to the limitations and disadvantages of the related art.

It is an object of the present disclosure to provide a light emitting device and a light emitting display device that include certain materials for the light emitting layer to improve both the efficiency and lifespan of the light emitting device, reduce the parasitic capacitance of the intermediate layer between the first and second electrodes including the light emitting layer, increase the threshold voltage of the capacitance of the intermediate layer and thereby improve reliability.

Additional advantages, objects, and features of the disclosure will be set forth in part in the description which follows and in part will become apparent to those having ordinary skill in the art upon examination of the following, or can be learned from practice of the disclosure. The objectives and other advantages of the disclosure can be realized and attained by the structure particularly pointed out in the written description and claims hereof as well as the appended drawings.

A light emitting device according to one or more embodiments of the present disclosure includes a first electrode and a second electrode facing each other, and an electron blocking layer, a first light emitting layer, and an electron transport layer between the first electrode and the second electrode, wherein the first light emitting layer includes a p-type host, a first n-type host, a second n-type host, and a dopant, a LUMO (lowest unoccupied molecular orbital) energy level of the first n-type host is higher than a LUMO energy level of the second n-type host, and hole mobility of the first n-type host is greater than hole mobility of the second n-type host and is smaller than hole mobility of the p-type host.

It is to be understood that both the foregoing general description and the following detailed description of the disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a sectional view illustrating a configuration of a light emitting device according to one or more embodiments of the present disclosure;

FIG. 2 is a schematic diagram illustrating the configuration of the light emitting layer of FIG. 1;

FIG. 3 shows an energy band diagram of a compound contained in the light emitting layer of FIG. 1;

FIG. 4 is a graph showing the threshold voltage at different ratios of first to second n-type hosts in the light emitting layer in the light emitting device according to one or more embodiments of the present disclosure;

FIG. 5 is a graph showing the efficiency at different ratios of first to second n-type hosts in the light emitting layer in the light emitting device according to one or more embodiments of the present disclosure;

FIG. 6 is a graph showing the lifespan at different ratios of first to second n-type hosts in the light emitting layer in the light emitting device according to one or more embodiments of the present disclosure;

FIG. 7 is a graph showing the J-V curve at different ratios of first to second n-type hosts of the light emitting device according to one or more embodiments of the present disclosure;

FIG. 8 is a graph showing the C-V curve at different ratios of first to second n-type hosts of the light emitting device according to one or more embodiments of the present disclosure;

FIG. 9 is a graph showing the threshold voltage of the capacitance at different ratios of first to second n-type hosts in the light emitting layer in the light emitting device according to one or more embodiments of the present disclosure;

FIG. 10 is a graph showing luminance characteristics at different ratios of first to second n-type hosts of a light emitting device according to one or more embodiments of the present disclosure;

FIG. 11 is a cross-sectional view illustrating a light emitting device according to one or more embodiments of the present disclosure; and

FIG. 12 is a cross-sectional view illustrating a light emitting display device according to one or more embodiments of the present disclosure.

### DETAILED DESCRIPTION OF THE EMBODIMENTS

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same can obscure the subject matter of the disclosure. In addition, the names of elements used in the following description are selected in consideration of clarity of description of the disclosure, and can differ from the names of elements of actual products. Further, the term “can” fully encompasses all the meanings and coverages of the term “may.” In addition, all the components of each organic light emitting diode (OLED) and each organic light emitting display device according to all embodiments of the present disclosure are operatively coupled and configured.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. Here, the electron that is first discharged from the material is the outermost electron that is most weakly confined and is in the HOMO energy level. NPD used as a standard in the experiments and tables of the present disclosure has a HOMO energy level of 5.5 eV and a LUMO energy level of −2.4 eV.

As used herein, the term “band gap energy (Eg)” is measured with an ultraviolet-visible spectrometer (UV-vis spectrometer).

As used herein, the term “LUMO energy level” is obtained by subtracting the band gap energy from the measured HOMO energy level of the material.

As used herein, the terms “HOMO energy level” and “LUMO energy level” are measured below the vacuum level of 0 eV, and are negative values. Upon comparison of the HOMO energy level and the LUMO energy level between materials, when the HOMO or LUMO energy level of one material is described as being larger or higher than another material, it is plotted at a higher level than the energy band diagram and has a small absolute value, and when the HOMO or LUMO energy level of one material is described as being smaller or lower than another material, it is plotted at a lower level than the energy band diagram and has a larger absolute value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt. %, or when the p-type material is present in an amount of less than 30 wt. %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling emittance spectrum curve, which is determined by the structure and optical characteristics of an organic light-emitting element including the thicknesses of organic layers such as, for example, an electron transport layer.

As used herein, a stack refers to a unit structure including a common layer including a hole transport layer and an electron transport layer, and a light emitting layer disposed between the hole transport layer and the electron transport layer, unless it is limited to a specific structure in one or more embodiments. The common layer can further include a hole injection layer, an electron blocking layer, a hole blocking layer, and an electron injection layer, and can further include other common layers depending on the structure or design of the light emitting device.

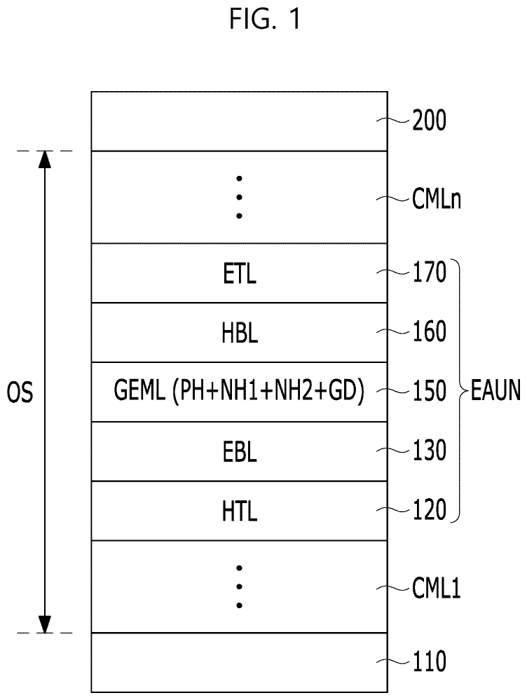

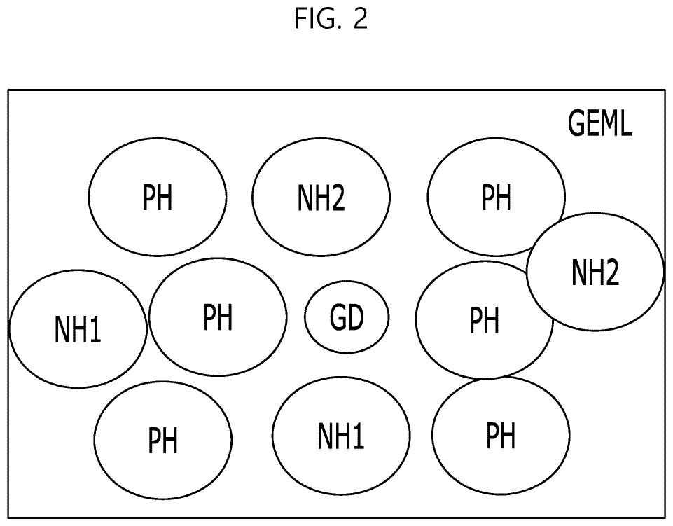

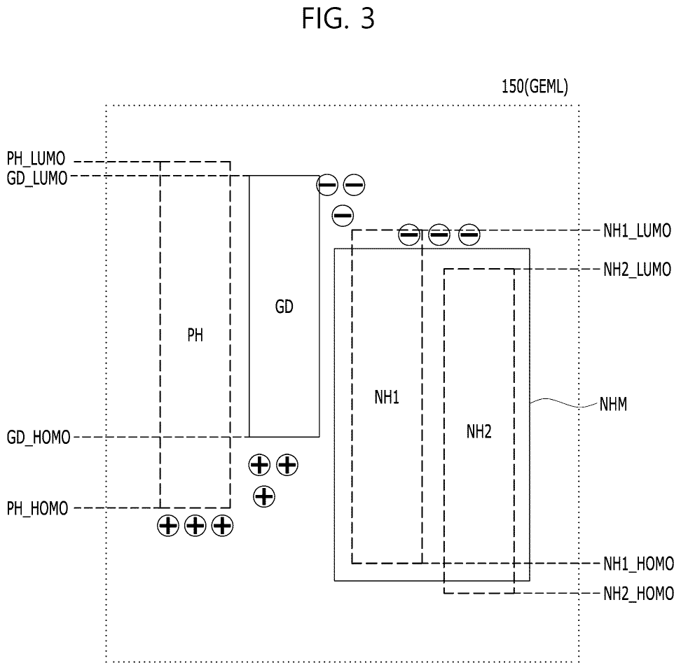

FIG. 1 is a sectional view illustrating a configuration of a light emitting device according to one or more embodiments of the present disclosure. FIG. 2 is a schematic diagram illustrating the configuration of the light emitting layer of FIG. 1. FIG. 3 shows an energy band diagram of a compound contained in the light emitting layer of FIG. 1.

As shown in FIG. 1, the light emitting device according to one or more embodiments of the present disclosure includes a first electrode 110 and a second electrode 200 facing each other, and an intermediate layer OS disposed between the first electrode 110 and the second electrode 200.

One of the first electrode 110 and the second electrode 200 can be an anode, and the other can be a cathode. FIG. 1 shows an example where the first electrode 110 is an anode and the second electrode 200 is a cathode, but the embodiment of the present disclosure is not limited thereto.

One of the first electrode 110 and the second electrode 200 is connected to the thin film transistor of each subpixel provided on the substrate and the other thereof receives a common voltage from a plurality of subpixels.

One of the first electrode 110 and the second electrode 200 can be a reflective electrode, and the other thereof can be a transparent electrode or a semi-transparent electrode. When the first electrode 110 is a transparent electrode and the second electrode 200 is a reflective electrode, the light emitting device emits light from the bottom. When the first electrode 110 is a reflective electrode and the second electrode 200 is a transparent electrode or a semi-transparent electrode, the light emitting device emits light from the top. In another embodiment of the present disclosure, each of the first electrode 110 and the second electrode 200 is formed as a non-reflective electrode, so that the light emitting device can emit light from both the top and bottom surfaces thereof. When the first electrode 110 is a reflective electrode, the reflective electrode can include multiple layers. For example, the reflective electrode can include a stack structure of ITO/Ag or Ag alloy/ITO, or Ag or Ag alloy/ITO.

The first electrode 110 is connected to the thin film transistor provided on the substrate to selectively receive a signal supplied to each subpixel, and the second electrode 200 is provided in common among the subpixels and receives a common voltage. When the device configuration of FIG. 1 is turned down, the second electrode 200 located in the lower area is connected to a thin film transistor, and the first electrode located in the upper area is provided throughout a plurality of subpixels to receive a common voltage.

An intermediate layer OS is provided between the first and second electrodes 110 and 200, and the light emission characteristics of the light emitting device can be controlled depending on the thickness of the intermediate layer OS and the layers provided in the intermediate layer OS. The intermediate layer OS can include a plurality of organic layers. One or more of the plurality of layers included in the intermediate layer OS can further contain a metal or an inorganic material other than metal. The inorganic material other than metal can be provided singly in one or more of the plurality of layers, or can form a complex with an organic material.

For example, the intermediate layer OS includes a first common layer CML1, a light emitting unit EAUN, and an nth common layer CMLn.

For example, the first common layer CML1 can be a hole injection layer HIL. The first common layer CML1 contacting the first electrode 110 can be formed of a hole injection material of a single organic or inorganic component, or can be formed by doping a hole transport material with a p-type dopant. The first common layer CML1 serves to reduce the barrier in supplying holes from the first electrode 110 to the intermediate layer 200.

The n^{th} common layer CMLn can be an electron injection layer EIL. The second common layer CMLn can contact the second electrode 200 and serve to reduce the barrier for electrons to be injected from the second electrode 200 to the intermediate layer OS. The electron injection layer EIL can include a halogen atom or an electron-transporting organic material combined with an alkali metal or alkaline earth metal.

At least one of the first common layer CML1 and the n^{th} common layer CMLn can have a multilayer structure. In some embodiments of the present disclosure, at least one of the first common layer CML1 and the n^{th} common layer CMLn can be another light emitting unit that emits the same color as the light emitting unit EAUN. A charge generation layer can be provided between adjacent light emitting units EAUN. In another embodiment of the present disclosure, at least one of the first common layer CML1 and the n^{th} common layer CMLn can be another light emitting unit that emits a different color from the light emitting unit EAUN.

The light emitting unit EAUN includes a hole transport layer HTL 120, an electron blocking layer EBL 130, a green light emitting layer GEML 150, a hole blocking Layer HBL 160 and an electron transport layer (ETL, 170).

The thickness or arrangement of at least one layer provided in the light emitting unit EAUN can be adjusted for each subpixel and can be distinguished from the first common layer CML1 and the n^{th} common layer CMLn commonly provided in the subpixels.

In a structure in which the light emitting layer emits different colors per subpixel, the green light emitting layer GEML 150 can be provided in the green subpixel, the red light emitting layer can be provided in the red subpixel, and the blue light emitting layer can be provided in the blue subpixel. In a structure in which the light emitting layer emits different colors per subpixel, a first common layer CML1, a hole transport layer HTL 120, an electron blocking layer EBL 130, a hole blocking layer HBL 160, and an electron transport layer ETL 170 can be commonly provided in each subpixel. In order to adjust the optical distance, etc., the thickness of at least one layer of the hole transport layer HTL 120, the electron blocking layer EBL 130, the hole blocking layer HBL 160, the electron transport layer (ETL, 170), and the nth common layer CMLn for each subpixel can be changed, at least one layer can be omitted from the subpixel of a specific color, or a hole auxiliary layer or an electron auxiliary layer can be added.

In a structure where the light emitting layer is different for each subpixel, the n^{th} common layer CMLn can be provided in common for each subpixel.

As shown in FIGS. 1 to 3, the green light emitting layer 150 includes a p-type host PH, a first n-type host NH1, a second n-type host NH, and a dopant GD. In the green light emitting layer 150 according to one or more embodiments of the present disclosure, the p-type host PH is highly capable of transporting holes to the dopant GD, and the first and second n-type hosts NH1 and NH2 are highly capable of transporting electrons to the dopant GD.

In the green light emitting layer 150, the p-type host PH is present in a larger amount than a total amount of the first and second n-type hosts NH1 and NH2, thereby supplying a sufficient quantity of holes to the dopant D.

The dopant GD in the green light emitting layer 150 has greater electron mobility than the hole mobility, so the p-type host PH is present in an amount greater than the total amount of the first and second n-type hosts NH1 and NH2 in the green light emitting layer 150, to sufficiently supply holes in the green light emitting layer 150 through control of the amount of the host.

In addition, the balance of exciton formation by hole-electron recombination is maintained by controlling the ratio of the p-type host PH to the first and second n-type hosts NH1 and NH2.

The n-type host material NH in the green light emitting layer 150 includes different n-type host materials NH1 and NH2, and thus has differences in HOMO-LUMO energy levels and hole mobility.

Specifically, the first and second n-type hosts NH1 and NH2 are n-type hosts having high electron mobility, but differ from each other in that the first n-type host NH1 is a higher LUMO energy level than the second n-type host NH2 closer to the HOMO-LUMO energy level of the dopant GD and has a higher hole mobility than the second n-type host NH2.

The first n-type host NH1, which has both high hole mobility and high electron mobility, transfers electrons to the dopant GD in the green light emitting layer 150 and simultaneously maintains the hole-electron balance in the dopant GD, thus serving to reduce the driving voltage of the light emitting device and increase lifespan thereof. For example, in response to the quantitatively abundant and continuous supply of holes from the p-type host PH, which is present in a great amount in the green light emitting layer 150, and two n-type hosts NH1 and NH2 supply electrons, the first n-type host NH1 having excellent electron mobility and excellent hole mobility can improve the lifespan of the light emitting device by continuously controlling the balance of holes and electrons in the dopant GD.

The second n-type host NH2 has high electron mobility, traps electrons transferred from the adjacent hole blocking layer 160 and/or the electron transport layer 170, quickly delivers the dopant GD through the first n-type host NH1, and maintains the high efficiency of the green light emitting layer 150. In addition, the second n-type host NH2 has the effects of increasing the threshold voltage of the capacitance of the light emitting device and of improving the reliability of the light emitting device.

Here, the electron mobility of the second n-type host NH2 can be greater than the electron mobility of the first n-type host NH1. This quickly traps electrons from the hole blocking layer 160 and/or the electron transport layer 170 in the second n-type host NH2 having a lower LUMO energy level, and smoothly transfers electrons to the first n-type host NH1 and the dopant GD in the green light emitting layer 150.

The LUMO energy level (NH1_LUMO) of the first n-type host NH1 can be lower than the LUMO energy level (GD_LUMO) of the dopant GD. The n-type host material NHM including the first and second n-type hosts NH1 and NH2 has excellent electron mobility although it has LUMO energy levels (NH1_LUMO, NH2_LUMO) lower than the LUMO energy level (GD_LUMO) of the dopant GD, facilitating transfer of electrons to the LUMO energy level (GD_LUMO) of the adjacent dopant GD.

The electron mobility in the green light emitting layer 150 can gradually increase in the order of the p-type host PH, the first n-type host NH1, the dopant GD, and the second n-type host NH2. The first n-type host NH1 has an electron mobility lower than that of the dopant GD, but has excellent hole mobility, so that based on excellent hole mobility of the first n-type host NH1, the first n-type host NH1 controls the hole-electron ratio over time in the green light emitting layer 150 and prevents deviation of hole-electron ratio that changes over time in the dopant GD in which the inherent electron mobility is predominant. Therefore, it is possible to maintain high luminous efficacy through continuous hole-electron recombination in the green light emitting layer 150, prevent charges not used for bonding from moving to the interface of the green light emitting layer 150, and prevent a decrease in lifespan.

The second n-type host NH2 is a material that has a low HOMO energy level and a low LUMO energy level, has high electron mobility, and serves to induce charge trapping of holes and electrons with the dopant GD. Through this, the second n-type host NH2 functions to increase efficiency and the capacitance threshold voltage of the light emitting device, and reduce the maximum capacitance value of the light emitting device.

When a single p-type host with excellent hole mobility and a single n-type host with excellent electron mobility are provided in the green light emitting layer, the initial luminous efficacy is excellent, but the balance between holes and electrons in the green dopant is not maintained, and the lifespan is much poorer than the embodiments of the present disclosure. This will be described later through experiments.

In addition, the LUMO energy level (PH_LUMO) of the p-type host PH is the highest among the components contained in the green light emitting layer 150. The LUMO energy level of the electron blocking layer 130 adjacent to the green light emitting layer 150 is higher than the LUMO energy level (PH_LUMO) of the p-type host, so that excitons or electrons do not move to the electron blocking layer 130 and remain in the green light emitting layer 150.

In the light emitting unit EAUN of the present disclosure, the hole transport layer 120 and the electron blocking layer 130 located below the green light emitting layer GEML 150 are layers related to hole transport. The hole transport layer 120 and the electron blocking layer 130 function to smoothly transfer holes injected from the first electrode 110 through the first common layer CML1 to the green light emitting layer 150. The HOMO energy level of the hole transport layer 120 and the electron blocking layer 130 is approximately lower than the HOMO energy level of the p-type host PH of the green emission layer 150.

The hole blocking layer 160 and the electron transport layer 170 located above the green light emitting layer GEML 150 are layers related to electron transport. In some cases, the hole blocking layer 160 can be omitted in the embodiments of the present disclosure. When the hole blocking layer 160 is omitted, the green light emitting layer 150 can directly contact the electron transport layer 170.

The LUMO energy levels of the hole blocking layer 160 and the electron transport layer 170 are higher than the LUMO energy levels of the first and second n-type hosts NH1 and NH2 of the green light emitting layer 150 to smoothly transfer electrons injected from the second electrode 200 to the green light emitting layer 150 through the n^{th} common layer CMLn.

Meanwhile, prior to description of the increase in capacitance threshold voltage mentioned as an effect of the second n-type host NH2, the meaning of capacitance threshold voltage will be described.

Capacitance threshold voltage refers to a reference voltage at which capacitance changes rapidly. In a C-V (capacitance-voltage) graph in which a voltage is plotted on the horizontal axis and capacitance is plotted on the vertical axis, the voltage at the point where the curve occurs is called “capacitance threshold voltage”.

Capacitance of the light emitting device is generated in the intermediate layer OS between the first electrode 110 and the second electrode 200. The capacitance of the intermediate layer OS is caused by the entire intermediate layer OS. However, in the embodiment of the present disclosure, by changing the composition of the green light emitting layer 150, the capacitance threshold voltage of the intermediate layer OS is increased, the fluctuation of capacitance between the first and second electrodes 110 and 200 can be reduced or prevented, and the light emitting device characteristics and FOS (front of screen test) characteristics related to the light emitting characteristics from the front when implemented as a light emitting display device are stabilized.

Among the plurality of layers constituting the intermediate layer OS, the green light emitting layer 150 has a different configuration from the subpixels that emit light of other colors. Among the configurations of the light emitting device shown in FIG. 1, layers other than the green light emitting layer 150 can be commonly provided in other subpixels.

When a light emitting display device includes a green subpixel, a red subpixel, and a blue subpixel, and emits white light, more green subpixels than other color subpixels are provided due to the high visibility and relative luminous efficacy thereof.

As a result, green subpixels have higher sensitivity due to electrical characteristics compared to other color subpixels. In particular, the green subpixel has a green light emitting layer and has a different configuration from the red light emitting layer.

The development of the light emitting layer has focused to date in the goals of lowering the driving voltage and increasing efficiency by maintaining the hole-electron balance between the hosts provided.

A light emitting device according to one or more embodiments of the present disclosure includes a green light emitting layer. In particular, the light emitting device prevents fluctuation in capacitance below the threshold voltage by increasing the capacitance threshold voltage in the light emitting device by the green light emitting layer in order to increase the reliability of the green light emitting layer 150 against changes over time, as well as driving voltage or efficiency. For this purpose, the light emitting device of the present disclosure includes a p-type host PH, a first n-type host NH1 having high hole mobility and electron mobility, and a second n-type host NH2 having high electron mobility, a low HOMO energy level, and a low LUMO energy level in the green light emitting layer, thereby reducing the driving voltage and efficiency, and continuously maintaining the hole-electron balance in the dopant GD, thereby improving luminous efficacy and the capacitance threshold voltage, reducing the sensitivity to capacitance changes in green light emitting devices and thereby improving device reliability.

In the light emitting device according to the embodiment of the present disclosure, a green light emitting layer is provided as an example of the light emitting layer, but a light emitting layer of other color is applicable. For example, the green light emitting layer is applicable to a case wherein, when a p-type host PH that mainly transfers holes to the dopant in the light emitting layer and an n-type host that mainly transfers electrons are provided, if an n-type host material NHM that transfers electrons is provided, and the energy band diagram of the dopant has a LUMO energy level that does not fall within the energy band diagram of the n-type host material NMH, an additional n-type host with a LUMO energy level closer to the LUMO energy level of the dopant material and a high hole mobility is provided.

When the capacitance threshold voltage is small, even a small voltage applied between the first and second electrodes can greatly change the capacitance of the light emitting device, causing a change in characteristics. Therefore, the light emitting device of the embodiment of the present disclosure increases the charge trapping efficiency in the light emitting layer using a p-type host PH and a second n-type host NH2 to increase the capacitance threshold voltage. In addition, the first n-type host NH1 has high hole mobility and controls the speed to supply abundant holes by the p-type host PH, ultimately allowing optimal recombination of holes and electrons in the dopant GD.

The dopant GD is present in an amount of 0.1 wt. % to 20 wt. % based on the total amount of the host and adjusts the wavelength of light emitted from the light emitting layer 150.

For example, the dopant GD can be a green dopant. The dopant GD can contain a heavy metal such as iridium or platinum as a core. For example, the dopant can be an iridium complex dopant. When the dopant GD emits green light, it can have an emission peak at a wavelength of 500 nm to 580 nm.

In the light emitting device of the embodiment of the present disclosure, for example, the dopant GD is a green dopant and is contained in the first and second n-type hosts NH1 and NH2 having two different physical properties from one p-type host PH, thus providing effects of reducing the driving voltage, improving efficiency and lifespan, lowering the maximum capacitance of the light emitting device, increasing the threshold voltage of the capacitance of the light emitting device, and stabilizing the C-V (capacitance-voltage) characteristics. Meanwhile, the embodiments of the present disclosure are not limited to the example of applying green dopants, but can also be applicable to dopants of other colors from the viewpoint of lowering the driving voltage, increasing luminous efficacy and lifespan, and stabilizing C-V characteristics.

Meanwhile, the total amount of the first and second n-type hosts NH1 and NH2 in the green light emitting layer GEML 150 can be smaller than the amount of the p-type host PH. When the total amount of the host in the green light emitting layer GEML 150 is set to 1 in consideration of all of the lifespan, efficiency, voltage change and threshold voltage of the light emitting device, the content of a single p-type host PH is 0.6 to 0.8 and the amount of the remaining hosts is the total amount of the first and second n-type hosts NH1 and NH2. When a ratio of the total host content to the p-type host PH content in the total amount of the host is higher than 0.8 or is not higher than 0.6, the hole-electron balance is not maintained in the green light emitting layer, which can lead to a decrease in efficiency and lifespan.

A plurality of hosts contained in the light emitting layer (EML) are first mixed to prepare a host mixture composition, the host mixture composition and a dopant are then supplied from different sources and co-deposited on the substrate on which the light emitting device is formed.

In the green light emitting layer (EML, 150), the dopant D, as well as the p-type host PH and the first and second n-type hosts NH1 and NH2, are evenly distributed throughout the layer and exciton generation occurs in the dopant distributed throughout the light emitting layer 150 through energy received from each host, thus resulting in light emission.

Meanwhile, the p-type host PH can contain a substituted or unsubstituted 3,3′-bicarbazole compound. For example, the p-type host PH can have the following Formula 1:

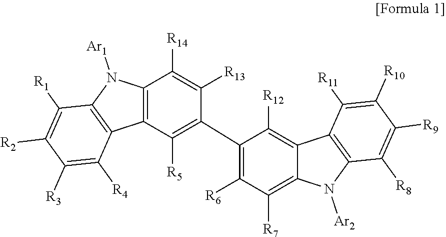

Ar₁ and Ar₂ are each independently selected from substituted or unsubstituted C6-C30 aryl and substituted or unsubstituted C5-C30 heteroaryl.

R₁ to R₁₄ are independently selected from hydrogen, deuterium, halogen, cyano (CN), C1-C20 alkyl, C3-C20 cycloalkyl, substituted or unsubstituted C6-C30 aryl, and substituted or unsubstituted C5-C30 heteroaryl.

The first n-type host NH1 can contain a triazene substituent or a pyrimidine substituent.

The second n-type host NH2 can have the following Formula 2:

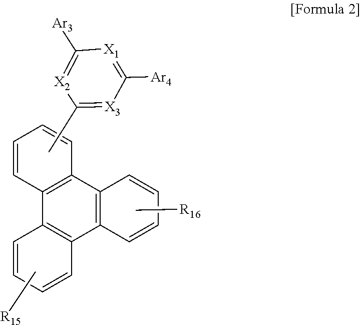

wherein at least two of X₁ to X₃ are nitrogen (N). When any one of X₁ to X₃ is not nitrogen (N), it can be C—R.

R, R₁₅, and R₁₆ are each independently selected from hydrogen, deuterium, halogen, cyano (CN), C1-C20 alkyl, C3-C20 cycloalkyl, substituted or unsubstituted C6-C30 aryl, and substituted or unsubstituted C5-C30 heteroaryl, and

Ar₃ and Ar₄ are independently selected from substituted or unsubstituted C6-C30 aryl, and substituted or unsubstituted C5-C30 heteroaryl.

The electron blocking layer 130 can be selected from materials that have hole transport property and have a large energy band gap and, in particular, a high LUMO energy level. The LUMO energy level of the electron blocking layer 130 can be at least 0.7 eV greater than the p-type host PH having the highest LUMO energy level in the green light emitting layer 150, and can be greater than 1 eV greater than the first n-type host NH1.

The HOMO energy level and LUMO energy level described herein are both negative values. When material A has a higher HOMO energy level or LUMO energy level than material B, this means that the absolute value of the HOMO energy level or LUMO energy level of material A is smaller than that of material B.

Table 1 below shows comparison in properties between the materials for the light emitting layer and the materials for adjacent layers used in the experiment.

TABLE 1

| | | | | | HOD driving voltage | EOD driving voltage |
|---|---|---|---|---|---|---|
| | | LUMO | | | [V] | [V] |
| Item | HOMO [eV] | [eV] | T1 [eV] | Eg [eV] | (@10 mA/cm²⁾) | (@10 mA/cm²⁾) |
| EBL | −5.35 | −1.88 | 2.83 | 3.47 | — | — |
| GD | −5.13 | −2.70 | 2.80 | 2.43 | 3.3 | 1.2 |
| PH | −5.62 | −2.64 | 2.92 | 2.98 | 2.3 | 13.0 |
| NH1 | −6.10 | −3.10 | 3.47 | 3.00 | 2.9 | 1.4 |
| NH2 | −6.24 | −3.49 | 3.63 | 2.75 | 7.6 | 0.9 |
| HBL | −5.36 | −2.77 | 2.67 | 2.59 | — | — |

As can be seen from FIG. 3 and Table 1, in the green light emitting layer 150, the LUMO energy level (NH1_LUMO) of the first n-type host NH1 is −3.10 eV, the LUMO energy level (NH2_LUMO) of the second n-type host NH2 is −3.49 eV, and the LUMO energy level (NH1_LUMO) of the first n-type host NH1 is higher than the LUMO energy level (NH2_LUMO) of the second n-type host NH2.

Table 1 shows the driving voltage measured at a current density of 10 mA/cm² in each of the HOD (hole only device) and EOD (electron only device) for each material of the green light emitting layer.

The HOD is used to detect the hole mobility of the test material. The HOD tested in Table 1 has a stack structure including a first electrode AND having a stack of ITO/Ag/ITO, a first hole injection layer HIL1 formed by co-deposition of a p-type dopant and a hole transport material, a hole transport layer HTL containing a hole transport material, a hole transport auxiliary layer G′ HTL, an electron blocking layer EBL, a green light emitting layer GEML including a test material doped with a green dopant, a second hole injection layer HIL2 and a second electrode CAT.

The EOD is used to detect the electron mobility of the test material. The EOD tested in Table 1 has a stack structure including a first electrode AND having a stack of ITO/Ag/ITO, a first electron injection layer EIL1 formed by co-deposition of an n-type dopant and an n-type charge generation material, a green light emitting layer GEML including a test material doped with a green dopant, a hole blocking layer HBL, an electron transport layer ETL, a second electron injection layer EIL2 and a second electrode CAT.

The p-type host PH has a driving voltage of 2.3V in the HOD, but has a driving voltage of 13.0V in the EOD. It can be seen that the resistance of hole transport is low, but the resistance of electron transport is high. In other words, it can be seen that the p-type host PH is a material that has excellent hole mobility, but very low electron mobility.

On the other hand, the first n-type host NH1 has a driving voltage of 2.9V in the HOD and a driving voltage of 1.4V in the EOD, which shows that the first n-type host NH1 exhibits both hole transport and electron transport. For example, the first n-type host NH1 is a material that has excellent hole mobility and electron mobility.

It can be seen that the second n-type host NH2 has a voltage of 7.6V in the HOD and has a voltage of 0.9V in the EOD, and has high resistance during hole transport and low resistance during electron transport. It can be seen that the second n-type host NH2 is a material that has high electron mobility, but low hole mobility.

In the experiment in Table 1, a large driving voltage in the HOD and the EOD means high resistance and the mobility is inversely proportional to the driving voltage.

As shown in Table 1, the LUMO energy level of the first n-type host NH1 is higher than the LUMO energy level of the second n-type host NH2.

In addition, the hole mobility of the first n-type host NH1 can be greater than the hole mobility of the second n-type host NH2 and can be smaller than the hole mobility of the p-type host PH.

At the same current density of the EOD device, the driving voltage of the second n-type host NH2 is smaller than that of the first n-type host NH1, which means that the electron mobility of the second n-type host NH2 is greater than that of the first n-type host NH1.

The LUMO energy level of the first n-type host NH can be lower than the LUMO energy level of the dopant.

As shown in Table 1, at the same current density of the EOD device in the green light emitting layer, the driving voltage gradually decreases in the order of the p-type host PH, the first n-type host NH1, the dopant GD, and the second n-type host NH2, and the electron mobility increases in the order of the p-type host PH, the first n-type host NH1, the dopant GD, and the second n-type host NH2.

The LUMO energy level of the p-type host PH is −2.64 eV, which is the highest among the components contained in the emitting layer, and the LUMO energy level of the electron blocking layer EBL is −1.88 eV, which is higher than the LUMO energy level of the p-type host PH. Since the LUMO energy level of the electron blocking layer EBL has a large difference and is higher than the LUMO energy levels of the materials contained in the green light emitting layer, it is possible to prevent electrons from escaping from the green light emitting layer through the electron blocking layer EBL.

As shown in Table 1, the energy band gap of the first n-type host NH1 is 3.0 eV, which is larger than the energy band gap of 2.75 eV of the second n-type host NH2.

Because the p-type host PH and the first and second n-type hosts NH1 and NH2 transfer the energy required for exciton formation to the triplet energy level of the dopant GD in the green light emitting layer GEML, the triplet energy levels of the p-type host PH and the first and second n-type hosts NH1 and NH2 can be greater than the triplet energy level of the red dopant. Among these, in terms of sequential transfer of electrons, the triplet energy level of the second n-type host NH2 can be greater than the triplet energy level of the first n-type host NH1.

For example, the HOMO energy level of the p-type host PH is −5.62 eV, which can be lower than the HOMO energy level of the dopant −5.13 eV. The HOMO energy level of the p-type host PH can be about 0.1 eV to about 0.6 eV lower than the HOMO energy level of the dopant GD.

The hole blocking layer HBL material not described in Table 1 has a HOMO energy level of −5.36 eV, which is lower than the HOMO energy level of the dopant GD, thus preventing holes from crossing from the green light emitting layer GEML.

Hereinafter, the device characteristics and capacitance-voltage characteristics of the light emitting device will be described based on experiments, while changing the contents of the p-type host material and the first and second n-type host materials in the light emitting layer.

The experiment was performed on Experimental Examples 1 to 5 (EX1, EX2, EX3, EX4, and EX5) having the same configuration except that the contents of the p-type host material and the first and second n-type host materials in the light emitting layer are different.

The stack configurations of the light emitting devices of Experimental Examples 1 to 5 (EX1 to EX5) can be seen from FIG. 1.

For example, the light emitting devices of Experimental Examples 1 to 5 include a first electrode AND 110 including a stack of ITO/Ag/ITO, a hole injection layer HIL formed by co-deposition with a p-type dopant and a hole transport material, a hole transport layer HTL 120 containing a hole transport material, a hole transport auxiliary layer G′ HTL, an electron blocking layer EBL 130, a green light emitting layer GEML 150 containing a combination of any one host material of Experimental Examples 1 to 5 (EX1 to EX5) doped with a green dopant, a hole blocking layer HBL 160, an electron transport layer ETL 170, an electron injection layer EIL, and a second electrode CAT 200.

In Experimental Example 1 (EX1) to Experimental Example 5 (EX5), the p-type host PH was commonly used in an amount of 0.7, and the balance of 0.3 corresponds to different ratios of the first to second n-type hosts NH1 and NH2. For example, in Experimental Example 1 (EX1), a single first n-type host NH1 was used at an amount of 0.3, and in Experimental Example 2 (EX2), a single second n-type host NH2 was used at an amount of 0.3. In Experimental Example 3 (EX3), the content ratio of the first n-type host NH1 to the second n-type host NH2 was 0.2:0.1, and in Experimental Example 4 (EX4), the content ratio of the first n-type host NH1 to the second n-type host NH2 was set to 0.15:0.15, and in Experimental Example 5 (EX5), the content ratio of the first n-type host NH1 to the second n-type host NH2 was 0.1:0.2.

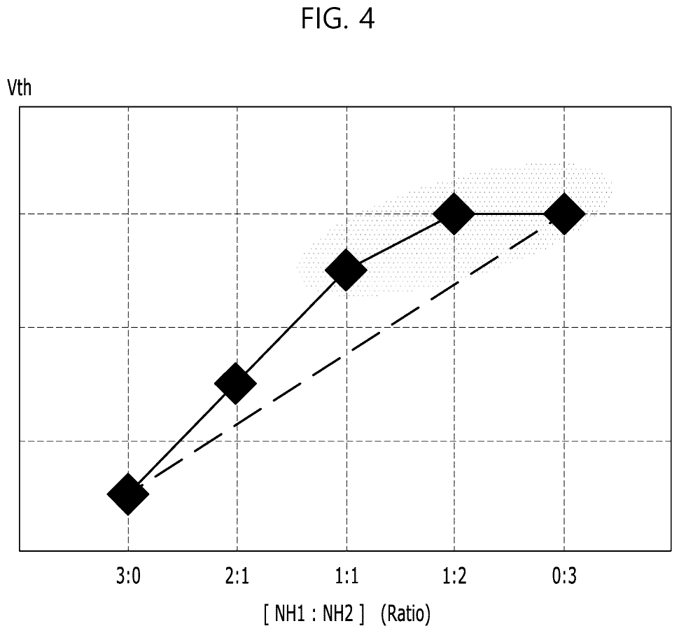

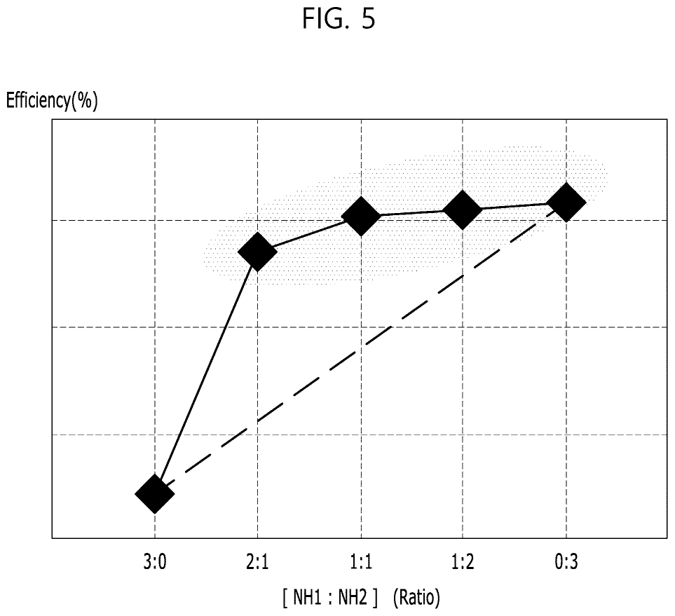

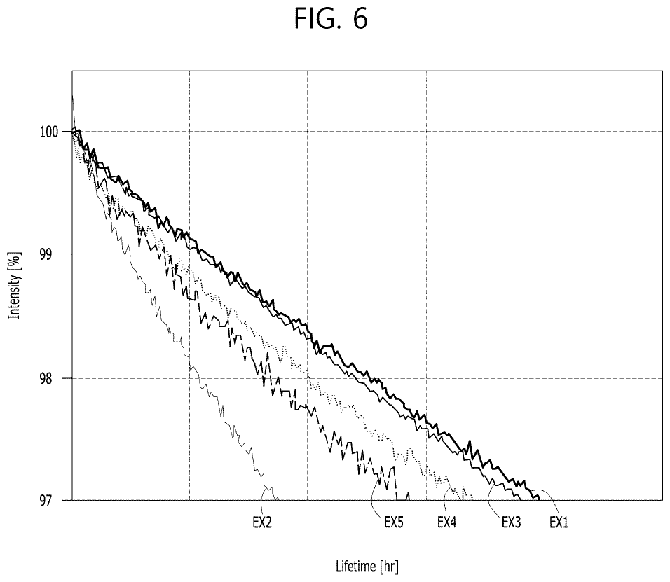

FIG. 4 is a graph showing the threshold voltage at different ratios of first to second n-type hosts in the light emitting layer in the light emitting device according to one or more embodiments of the present disclosure. FIG. 5 is a graph showing the efficiency at different ratios of first to second n-type hosts in the light emitting layer in the light emitting device according to one or more embodiments of the present disclosure. FIG. 6 is a graph showing the lifespan at different ratios of first to second n-type hosts in the light emitting layer in the light emitting device according to one or more embodiments of the present disclosure.

Based on the experiments in Table 2 and FIGS. 4 to 6, the device characteristics were evaluated while changing the contents of the p-type host material and the first and second n-type host materials in the light emitting layer, and the capacitance-voltage characteristics of the light emitting device are evaluated through the experiments in Table 3.

TABLE 2

| | | | | Device characteristics | | | |
|---|---|---|---|---|---|---|---|
| | Host content ratio | | | | | Efficiency | Lifespan |
| Item | PH | NH1 | NH2 | ΔVth[V] | ΔV[V] | (%) | (%) |
| EX1 | 0.7 | 0.3 | 0.0 | −0.05 | −0.1 | 97 | 217 |
| EX2 | 0.7 | 0.0 | 0.3 | 0.00 | 0.0 | 100 | 100 |
| EX3 | 0.7 | 0.2 | 0.1 | −0.03 | −0.1 | 99 | 213 |
| EX4 | 0.7 | 0.15 | 0.15 | −0.01 | −0.1 | 100 | 198 |
| EX5 | 0.7 | 0.1 | 0.2 | 0.00 | 0.0 | 100 | 163 |

The threshold voltage change (ΔVth), driving voltage change (ΔV), efficiency, C-V characteristics and efficiency were obtained by conducting the experiment at a luminance of the light emitting device at 600 nits and at 25° C., and the lifespan was measured in an accelerated environment of a brightness of the light emitting device of 600 nits and at 35° C. Lifespan was time taken until the luminance reaches 95% of the initial luminance.

In Table 1, the threshold voltage change, driving voltage change, efficiency, and lifespan were compared and evaluated based on the case where the second n-type host NH2 with high electron mobility was used alone.

As shown in FIG. 4 and Table 1, as the content of the second n-type host NH2 increases, the threshold voltage of the light emitting device increases, and as the content of the first n-type host NH1 increases, the threshold voltage decreases.

In addition, Experimental Example 1 (EX1) and Experimental Examples 3 to 5 (EX3, EX4, and EX5) using the first n-type host NH1 as the n-type host exhibits lower driving voltage than Experimental Example 2 (EX2) in which only a single second n-type host NH2 is used as the n-type host.

In addition, as shown in FIG. 5 and Table 1, all of Experimental Examples 2 to 5 (EX2, EX3, EX4, EX5) including the second n-type host NH2 have a similar efficiency of 99% or more.

As shown in FIG. 6 and Table 1, Experimental Example 2 (EX2) using only a single second n-type host NH2 as an n-type host exhibits the lowest lifespan, and Experimental Example 1 (EX1) and Experimental Examples 3 to 5 (EX3, EX4, EX5) using only a single second-type host NH1 as an n-type host exhibit an increase in lifespan of 163% or more.

In other words, the second n-type host NH2 as a single n-type host exhibits excellent device characteristics, but has a limitation of material lifespan, and the single first n-type host NH1 has long life characteristics, but low efficiency. A combination of the first and second n-type hosts NH1 and NH2 is particularly advantageous in terms of lifespan.

Hereinafter, the contents of the p-type host material and the first and second n-type host materials in the light emitting layer were varied in the experiment of Table 3 using the light emitting devices of Experimental Examples 1 to 5 (EX1 to EX5), to obtain C-V characteristics and initial luminance.

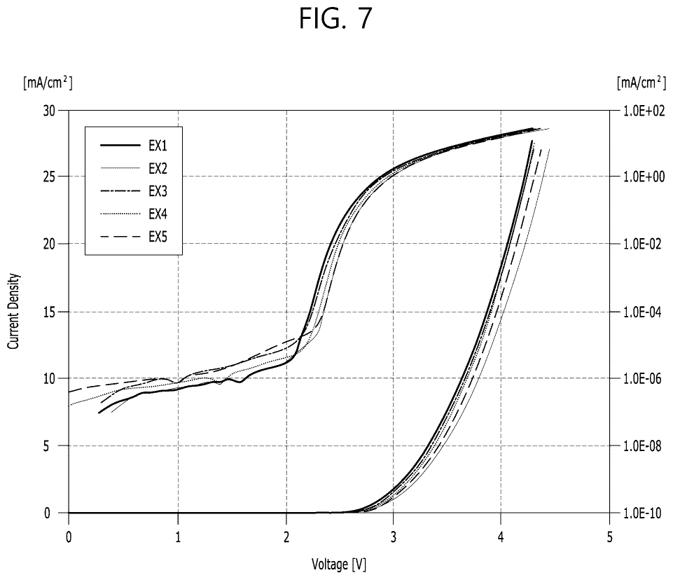

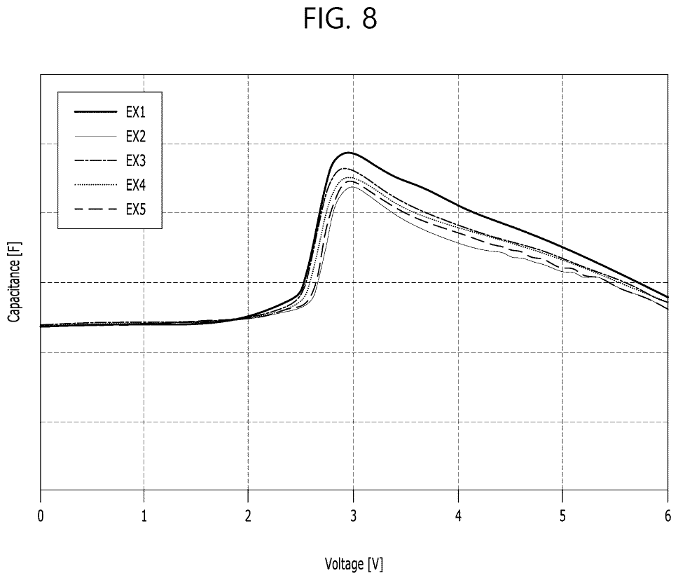

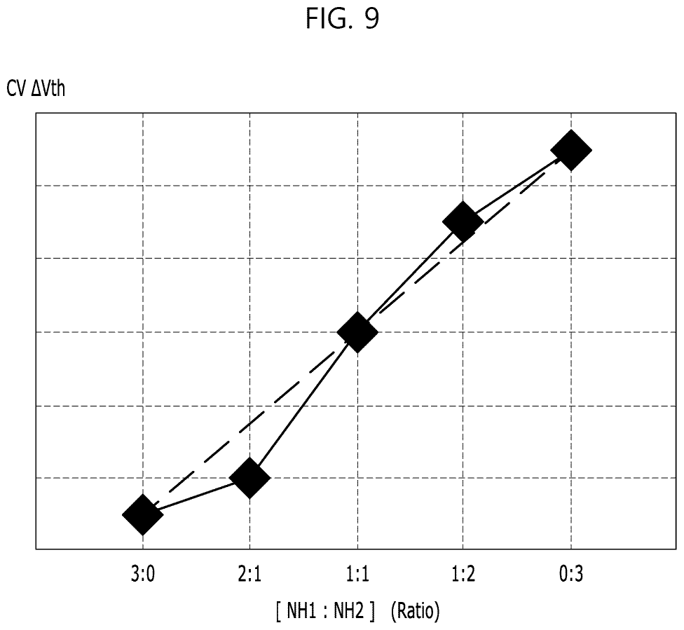

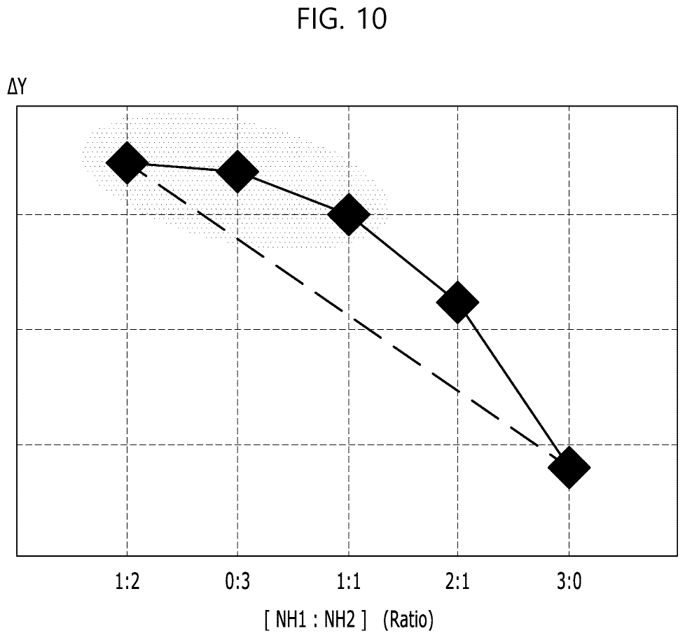

FIG. 7 is a graph showing the J-V curve at different ratios of first to second n-type hosts of the light emitting device according to one or more embodiments of the present disclosure. FIG. 8 is a graph showing the C-V curve at different ratios of first to second n-type hosts of the light emitting device according to one or more embodiments of the present disclosure. FIG. 9 is a graph showing the threshold voltage of the capacitance at different ratios of first to second n-type hosts in the light emitting layer in the light emitting device according to one or more embodiments of the present disclosure. FIG. 10 is a graph showing luminance characteristics at different ratios of first to second n-type hosts of a light emitting device according to one or more embodiments of the present disclosure.

TABLE 3

| | Host content ratio | | | C-V characteristics | | FFR/SFR |
|---|---|---|---|---|---|---|
| Item | PH | NH1 | NH2 | CV Vth[V] | Max Cap[F] | ΔY(%) |
| EX1 | 0.7 | 0.3 | 0.0 | 2.40 | 2.43E−09 | 40 |
| EX2 | 0.7 | 0.0 | 0.3 | 2.57 | 2.18E−09 | 72 |
| EX3 | 0.7 | 0.2 | 0.1 | 2.43 | 2.32E−09 | 65 |
| EX4 | 0.7 | 0.15 | 0.15 | 2.47 | 2.26E−09 | 70 |
| EX5 | 0.7 | 0.1 | 0.2 | 2.50 | 2.18E−09 | 73 |

In the experiment in Table 3, the capacitance threshold voltage (CV Vth) and the maximum capacitance of the light emitting device were evaluated in terms of capacitance-voltage (C-V) characteristics for Experimental Examples 1 to 5 (EX1 to EX5), and the luminance of the initial frame was compared with the luminance of the sixth frame and evaluated (ΔY: FFR/SFR).

The maximum capacitance of the light emitting device must be reduced and the capacitance threshold voltage (CV Vth) must be large to reduce the volatility of the light emitting device due to changes in voltage or temperature.

The voltage at which the curve is generated in the C-V graph of FIG. 8 is the capacitance threshold voltage and Experimental Example 2 (EX2) exhibits superior capacitance threshold voltage.

In addition, as shown in Table 3, when the content of the second n-type host NH2 is increased in Experimental Examples 1 to 5 (EX1 to EX5), the maximum capacitance of the light emitting device decreases.

Referring to FIG. 10 and Table 3, when comparing the luminance of the initial frame in Experimental Examples 1 to 5 (EX1 to EX5) with the luminance of the sixth frame, when the luminance of the first n-type host NH1 is used alone, the initial luminance is very low, and when at least a part of the second n-type host NH2 is contained, the initial luminance is 65% or more.

In addition, as can be seen from FIG. 8, the capacitance of Experimental Example 2 (EX2) changes at a relatively high voltage. In addition, as shown in FIG. 10, Experimental Example 2 (EX2) has relatively excellent initial luminance. On the other hand, as shown in FIGS. 8 and 10, in Experimental Example 1 (EX1), the capacitance changes at low voltage and the initial luminance is very low.

For example, it can be seen from the experiments of FIGS. 8 to 10 and Table 3that Experimental Example 2 (EX2) exhibits excellent C-V and luminance (ΔY) characteristics when a single second n-type host NH2 is used. As can be seen from the experiments in Table 2 and FIG. 6, Experimental Example 2 (EX2) has a great limitation of lifespan and the driving voltage is higher than that of other experimental examples. In addition, Experimental Example 1 (EX1) using a single first n-type host NH1 has long lifespan, but very poor efficiency and initial luminance, and large maximum capacitance of the light emitting device, thus making it difficult to satisfy the required efficiency of the light emitting device.

The light emitting device of the present disclosure has excellent device characteristics including driving voltage, efficiency, and lifespan in the green light emitting layer, but also has a capacitance threshold voltage higher than a predetermined level for stabilizing C-V characteristics in terms of reliability that secures a predetermined luminance in the temperature change or initial frame state and to change the host of the light emitting layer to obtain a structure that can lower the maximum capacitance of the light emitting device. In Experimental Examples 1 to 5 described above, the content of the p-type host is greater than a total amount of the first and second n-type hosts and the content ratio of the first n-type host to the second n-type host was set to 1:1 (0.15:0.15), all characteristics were optimally excellent.

In the following experiment, the device characteristics were evaluated by changing the content of the p-type host in a structure containing three hosts in the light emitting layer, compared to Experimental Example 2 as a representative example of the two hosts in the light emitting layer.

TABLE 4

| | | | | Device characteristics | | | |
|---|---|---|---|---|---|---|---|
| | Host content ratio | | | | | Efficiency | Lifespan |
| Item | PH | NH1 | NH2 | ΔVth[V] | ΔV[V] | (%) | (%) |
| EX2 | 0.7 | 0.0 | 0.3 | 0.00 | 0.0 | 100 | 100 |
| EX6 | 0.6 | 0.2 | 0.2 | −0.02 | −0.1 | 98 | 91 |
| EX4 | 0.7 | 0.15 | 0.15 | −0.01 | −0.1 | 100 | 198 |
| EX7 | 0.8 | 0.1 | 0.1 | −0.01 | 0.0 | 96 | 97 |

In Experimental Example 2 (EX2), only the second n-type host NH2 was used as a single n-type host, and in Experimental Example 6 (EX6), Experimental Example 4 (EX4), and Experimental Example 7 (EX7), the content ratio of the first and second n-type hosts NH1 and NH2 was 1:1 and the content of the p-type host PH gradually increased. For example, in Experimental Example 6 (EX6), the content ratio of the p-type host, the first n-type host, and the second n-type host was 0.6:0.2:0.2, and in Experimental Example 4 (EX4), the p-type host, the first n-type host and the second n-type host were set to 0.7:0.15:0.15, and in Experimental Example 7 (EX7), the content ratio of the p-type host, the first n-type host, and the second n-type host was 0.8:0.1:0.1.

The results in Table 4 show that Experimental Example 4 (EX4) is excellent in all of the threshold voltage change, driving voltage change, efficiency, and lifespan of the light emitting device.

In addition, it can be seen that when the content of the p-type host PH to each of the first and second n-type hosts NH1 and NH2 is 3 times or less or 8 times or more, the effectiveness in efficiency and lifespan decreases. For example, in the embodiments of the present disclosure, when the content of the p-type host PH to each content of the first and second n-type hosts NH1 and NH2 is set to be greater than 3 times and less than 8 times, efficiency, driving voltage, and long lifespan are advantageous. In this case, the first n-type host and the second n-type host can be present at approximately equal amounts in the light emitting layer.

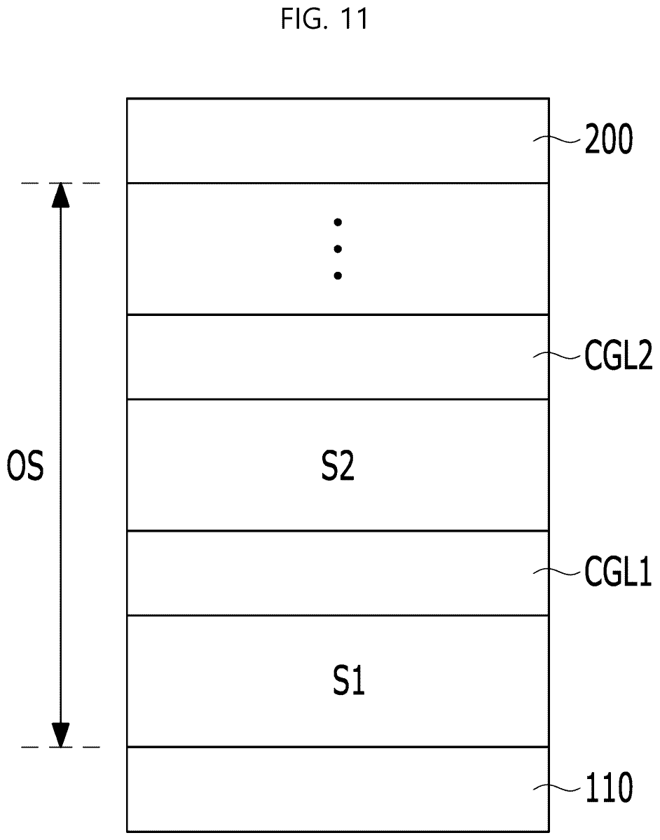

FIG. 11 is a cross-sectional view illustrating a light emitting device according to one or more embodiments of the present disclosure.

As shown in FIG. 11, the light emitting device according to one or more embodiments of the present disclosure has an intermediate layer OS having two or more stacks (S1, S2, . . . ) emitting light of the same color between the first and second electrodes 110 and 200. Each stack (S1, S2, . . . ) can be divided into charge generation layers (CGL1, CGL2, . . . ).

Each stack (S1, S2, . . . ) can include a light emitting unit EAUN including a hole transport layer HTL, an electron blocking layer EBL, a light emitting layer 150, a hole blocking layer HBL, and an electron transport layer ETL shown in FIG. 1 above. In some cases, the hole transport layer HTL can further include a hole transport auxiliary layer thereunder or thereon.

The light emitting layer of each stack includes a p-type host PH having excellent hole mobility, first and second n-type hosts NH1 and NH2 having different physical properties described above, and a dopant GD.

The first and second n-type hosts NH1 and NH2 differ from each other in that the LUMO energy level of the first n-type host NH1 is higher than the LUMO energy level of the second n-type host NH2, and the hole mobility of the first n-type host NH1 is higher than the hole mobility of the second n-type host NH2 and is lower than the hole mobility of the p-type host PH.

The electron mobility of the second n-type host NH2 can be greater than the electron mobility of the first n-type host NH1.

The first n-type host NH1 is different from the second n-type host NH2 in that it has a high LUMO energy level and has high hole mobility and high electron mobility.

In addition, the LUMO energy level of the first n-type host NH1 can be lower than the LUMO energy level of the dopant GD.

When a plurality of stacks are provided, it is possible to obtain the effects of further improving the luminous efficacy of the light emitting layer, providing reduced threshold voltage, improved luminous efficacy, and long lifespan, of the light emitting device described in Experimental Examples 3, 4 and 5 (EX3, EX4, and EX5), and improving device stability through increased threshold voltage of the capacitance.

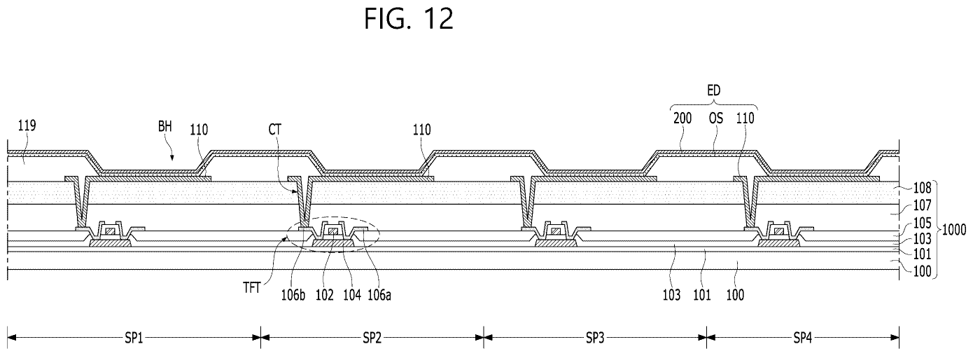

FIG. 12 is a cross-sectional view illustrating a light emitting display device according to one or more embodiments.

As shown in FIG. 12, the light emitting display device according to one or more embodiments allows application to the light emitting device to at least one of a plurality of subpixels SP1, SP2, SP3 and SP4.

The light emitting display of the present disclosure includes a substrate 100 having a plurality of subpixels, a light emitting device ED commonly provided on the substrate 100, and a thin film transistor TFT provided in each of the subpixels and connected to the first electrode 110 of the light emitting device ED.

The thin film transistor TFT includes, for example, a gate electrode 102, a semiconductor layer 104, and a source electrode 106a and a drain electrode 106b connected to respective sides of the semiconductor layer 104. In addition, a channel protection layer can be further provided in the portion where the channel of the semiconductor layer 104 is located in order to prevent direct connection between the source/drain electrodes 106a and 106b and the semiconductor layer 104. A buffer layer 101 on the substrate 100 can be disposed on the substrate 100 and the thin film transistor TFT can be located on the buffer layer 101.

A gate insulating layer 103 is provided between the gate electrode 102 and the semiconductor layer 104.

The semiconductor layer 104 can be formed of, for example, an oxide semiconductor, amorphous silicon, polycrystalline silicon, or a combination thereof. For example, when the semiconductor layer 104 is an oxide semiconductor, the heating temperature required for forming the thin film transistor can be lowered, and thus the substrate 100 can be freely used and the semiconductor layer 104 is advantageously applied to a flexible display device.

A gate electrode 102 can be provided on the gate insulating film 103, and an interlayer insulating film 105 can be further provided between the gate electrode 102 and the source electrode 106a/drain electrode 106b.

In addition, the drain electrode 106b of the thin film transistor TFT can be connected to the first electrode 110 in a contact hole CT provided in the first and second passivation layers 107 and 108.

The first passivation layer 107 is provided to primarily protect the thin film transistor TFT, and color filters 109R, 109G, and 109B can be provided on the first passivation layer 107.

A second passivation layer 108 is provided on the first passivation layer 107 including the color filters 109R, 109G, and 109B.

When the plurality of subpixels includes a red subpixel, a green subpixel, a blue subpixel, and a white subpixel, the device structure described in FIG. 1 or 9 can be applied to the light emitting device ED in at least the red subpixel. In some cases, the light emitting layer in each subpixel can be divided and patterned. A hole transport auxiliary layer can be provided in some of subpixels with different emission colors, and may not be provided in the remainder thereof. In subpixels with different emission colors, a hole transport auxiliary layer is further provided to compensate for the optical distance. For example, the hole transport auxiliary layer in a red subpixel can be thicker than the hole transport auxiliary layer in a green subpixel or a blue subpixel.

A second passivation layer 108 is formed under the first electrode 110 to cover the first to third color filters 109R, 109G, and 109B. The first electrode 110 is formed on the surface of the second passivation layer 108 excluding the contact hole CT, is connected to either the drain electrode 106b or the source electrode 106a of the thin film transistor TFT and receives an electrical signal from the thin film transistor TFT.

Here, a configuration including the substrate 100, the thin film transistor TFT, and the first and second passivation layers 107 and 108 can be defined as the thin film transistor array substrate 1000.

The light emitting device ED is formed on the thin film transistor array substrate 1000 including the bank 119 defining the light emitting portion BH. The light emitting device ED includes a transparent first electrode 110, a reflective and transparent second electrode 200 facing the first electrode 110, and an intermediate layer OS shown in FIG. 1 or FIG. 11, between the first and second electrodes 110 and 200, as described above. For example, when the red subpixel is provided with the light emitting device ED of FIG. 1 or 11, the remaining subpixels also include a first common layer CML1, a hole transport layer HTL, an electron blocking layer EBL, a hole blocking layer HBL, an electron transport layer ETL, an n^{th} common layer CML2, or a charge generation layer CGL can be continuous. The energy band gap can be different depending on the dopant provided in each light emitting layer, and the use of the host and the use of the light emitting dopant can be different.

Therefore, when the green light emitting layer of the green subpixel is formed using two types of n-type hosts and one type of p-type host, the light emitting layers of other color subpixels can be formed using a single p-type host or a single n-type host, or a plurality of p-type hosts or a plurality of n-type hosts, or both a plurality of p-type hosts and a plurality of n-type hosts.

Since the energy band gap of the green dopant of the host used in the light emitting layer of a different color is different from that of the green dopant, at least one of the hosts contained in the green light emitting layer can be different for optimal light emission.

The first electrode 110 is divided into respective subpixels, and the remaining layers of the light emitting device ED excluding the first electrode 110 are integrally provided in the entire display area, regardless of respective subpixels.

Either the first electrode 110 or the second electrode 200 can be connected to a thin film transistor TFT.

A capping layer is provided on the second electrode 200 to improve light emission efficiency and protect the light emitting device ED in some embodiments.

An encapsulation layer or an encapsulation substrate can be further provided on the second electrode 200 to protect the light emitting device ED in some embodiments.

Although the illustrated example is shown considering top emission, the embodiments of the present disclosure are not limited thereto.

The light emitting device according to the embodiment of the present disclosure includes the light emitting layer containing an n-type host configured to control electron transport, the n-type host includes a first n-type host having a high LUMO energy level, high hole mobility, and high electron mobility, and a second n-type host having a lower LUMO energy level, lower hole mobility, and higher electron mobility than the first n-type host. The light emitting layer further includes a p-type host to supply sufficient holes to act along with the n-type host and a dopant.

The first n-type host which has a high LUMO energy level and high hole mobility and high electron mobility controls the rates of electrons and holes supplied to the green dopant, thereby allowing the balance during recombination of holes and electrons supplied in sufficient amounts due to the high content of the p-type host, maintaining the hole-electron balance in the light emitting layer, and improving the charge trapping efficiency in the light emitting layer to maintain or increase the capacitance threshold voltage of the light emitting layer in the light emitting device.

A light emitting device according to some embodiments of the present disclosure can further comprise a first electrode and a second electrode facing each other, and an electron blocking layer, a first light emitting layer, and an electron transport layer between the first electrode and the second electrode. The first light emitting layer can comprise a p-type host, a first n-type host, a second n-type host, and a dopant. A LUMO energy level of the first n-type host can be higher than a LUMO energy level of the second n-type host. Also, a hole mobility of the first n-type host can be greater than a hole mobility of the second n-type host and can be smaller than a hole mobility of the p-type host.

In a light emitting device according to some embodiments of the present disclosure, an electron mobility of the second n-type host can be greater than an electron mobility of the first n-type host.

In a light emitting device according to some embodiments of the present disclosure, the LUMO energy level of the first n-type host can be lower than a LUMO energy level of the dopant.

In a light emitting device according to some embodiments of the present disclosure, the electron mobility in the light emitting layer can gradually increase in order of the p-type host, the first n-type host, the dopant, and the second n-type host.

In a light emitting device according to some embodiments of the present disclosure, a LUMO energy level of the p-type host can be the highest among LUMO energy levels of components contained in the light emitting layer. A LUMO energy level of the electron blocking layer can be higher than the LUMO energy level of the p-type host.

In a light emitting device according to some embodiments of the present disclosure, an energy band gap of the first n-type host can be greater than an energy band gap of the second n-type host.

In a light emitting device according to some embodiments of the present disclosure, a triplet energy level of the second n-type host can be greater than a triplet energy level of the first n-type host.

In a light emitting device according to some embodiments of the present disclosure, a HOMO energy level of the p-type host can be 0.1 eV to 0.6 eV lower than a HOMO energy level of the dopant.

In a light emitting device according to some embodiments of the present disclosure, a total content of the first n-type host and the second n-type host can be smaller than a content of the p-type host.

In a light emitting device according to some embodiments of the present disclosure, the content of the p-type host can be 3 to 8 times each of the content of the first n-type host and the content of the second n-type host.

In a light emitting device according to some embodiments of the present disclosure, the first n-type host and the second n-type host can be present in approximately equal amounts in the light emitting layer.

In a light emitting device according to some embodiments of the present disclosure, the dopant can have an emission peak at a wavelength of 500 nm to 580 nm.

A light emitting device according to some embodiments of the present disclosure can further comprise a hole blocking layer between the first light emitting layer and the electron transport layer.

A light emitting device according to some embodiments of the present disclosure can further comprise one or more stacks at least one of between the first electrode and the electron blocking layer or between the electron transport layer and the second electrode. The at least one stack can comprise a first common layer, a second light emitting layer, and a second common layer, and the second light emitting layer emits the same color as the first light emitting layer.

In a light emitting device according to some embodiments of the present disclosure, the second light emitting layer can comprise the p-type host, the first n-type host, the second n-type host, and a green dopant.

A light emitting display device according to some embodiments of the present disclosure can comprise a substrate including a plurality of subpixels, a thin film transistor provided in each of the plurality of subpixels and a light emitting device described above, the light-emitting device being connected to the thin film transistor in the plurality of subpixels.

The light emitting device and the light emitting display according to the present disclosure have the following effects.

The light emitting device according to one or more embodiments of the present disclosure includes a light emitting layer including a p-type host, a first n-type host, a second n-type host, and a dopant. The LUMO energy level of the first n-type host is higher than the LUMO energy level of the second n-type host, and the hole mobility of the first n-type host is greater than the hole mobility of the second n-type host, and is smaller than the hole mobility of the p-type host.

In the light emitting device according to some embodiments of the present disclosure, the first n-type host which has a high LUMO energy level and high hole mobility and high electron mobility controls the rates of electrons and holes supplied to the green dopant, thereby allowing the balance during recombination of holes and electrons supplied in sufficient amounts due to the high content of the p-type host, maintaining the hole-electron balance in the light emitting layer, and improving the charge trapping efficiency in the light emitting layer to maintain or increase the capacitance threshold voltage of the light emitting layer in the light emitting device.

In the light emitting device according to the embodiment of the present disclosure, it is possible to supply holes and electrons at high rates to the light emitting layer by the p-type host and the second n-type host, to prevent excitons or electrons from escaping to the electron blocking layer through charge trapping, to prevent stress at the interface between the electronic blocking layer and the light emitting layer through optimized mobility balance by the mixed host and thereby improve long lifespan characteristics.

In the light emitting device according to some embodiments of the present disclosure, the p-type host is provided in a larger amount than the n-type host to balance the high electron mobility of the dopant in the light emitting layer, improve charge trapping by abundant hole supply, maintain the threshold voltage characteristics of the light emitting device, improve the capacitance threshold voltage by the second n-type host, and thereby improve the reliability of the device.

By changing the materials for the light emitting layers, the light emitting device according to the present disclosure and the light emitting display device including the same are capable of improving luminous efficacy, reducing driving voltage, power consumption and environmental pollution, providing sustainable effects of increasing lifespan, and realizing ESG (environmental/social/governance).

It will be apparent to those skilled in the art that various modifications and variations can be made in the disclosure without departing from the spirit or scope of the disclosure. Thus, it is intended that the disclosure covers such modifications and variations thereof, provided they fall within the scope of the appended claims and their equivalents.

What is claimed is:

1. A light emitting device comprising:
a first electrode and a second electrode facing each other, and
an electron blocking layer, a first light emitting layer, and an electron transport layer between the first electrode and the second electrode,
wherein the first light emitting layer comprises a p-type host, a first n-type host, a second n-type host, and a dopant,
wherein a lowest unoccupied molecular orbital (LUMO) energy level of the first n-type host is higher than a LUMO energy level of the second n-type host, and
wherein a hole mobility of the first n-type host is greater than a hole mobility of the second n-type host and is smaller than a hole mobility of the p-type host.

2. The light emitting device according to claim 1, wherein an electron mobility of the second n-type host is greater than an electron mobility of the first n-type host.

3. The light emitting device according to claim 1, wherein the LUMO energy level of the first n-type host is lower than a LUMO energy level of the dopant.

4. The light emitting device according to claim 1, wherein the electron mobility in the light emitting layer gradually increases in order of the p-type host, the first n-type host, the dopant, and the second n-type host.

5. The light emitting device according to claim 1, wherein a LUMO energy level of the p-type host is the highest among LUMO energy levels of components contained in the light emitting layer, and
wherein a LUMO energy level of the electron blocking layer is higher than the LUMO energy level of the p-type host.

6. The light emitting device according to claim 1, wherein an energy band gap of the first n-type host is greater than an energy band gap of the second n-type host.

7. The light emitting device according to claim 1, wherein a triplet energy level of the second n-type host is greater than a triplet energy level of the first n-type host.

8. The light emitting device according to claim 1, wherein a highest occupied molecular orbital (HOMO) energy level of the p-type host is 0.1 eV to 0.6 eV lower than a HOMO energy level of the dopant.

9. The light emitting device according to claim 1, wherein a total content of the first n-type host and the second n-type host is smaller than a content of the p-type host.

10. The light emitting device according to claim 9, wherein the content of the p-type host is 3 to 8 times of the content of the first n-type host or the content of the second n-type host.

11. The light emitting device according to claim 10, wherein the first n-type host and the second n-type host are present in approximately equal amounts in the light emitting layer.

12. The light emitting device according to claim 1, wherein the dopant has an emission peak at a wavelength of 500 nm to 580 nm.

13. The light emitting device according to claim 1, further comprising a hole blocking layer between the first light emitting layer and the electron transport layer.

14. The light emitting device according to claim 1, further comprising at least one stack disposed between the first electrode and the electron blocking layer and/or between the electron transport layer and the second electrode,
wherein the at least one stack comprises a first common layer, a second light emitting layer, and a second common layer, and
wherein the second light emitting layer emits a same color as the first light emitting layer.

15. The light emitting device according to claim 14, wherein the second light emitting layer comprises the p-type host, the first n-type host, the second n-type host, and a green dopant.

16. The light emitting device according to claim 1, wherein the p-type host comprises a substituted or unsubstituted 3,3′-bicarbazole compound.

17. The light emitting device according to claim 1, wherein the p-type host comprises a compound of Formula 1: 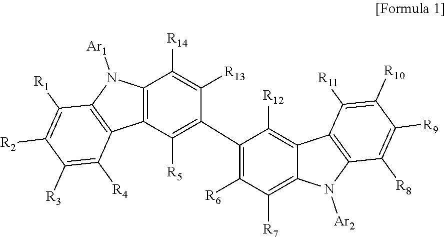
wherein:
Ar₁ and Ar₂ are each independently selected from substituted or unsubstituted C6-C30 aryl and substituted or unsubstituted C5-C30 heteroaryl; and
R₁ to R₁₄ are independently selected from hydrogen, deuterium, halogen, cyano (CN), C1-C20 alkyl, C3-C20 cycloalkyl, substituted or unsubstituted C6-C30 aryl, and substituted or unsubstituted C5-C30 heteroaryl.

18. The light emitting device according to claim 1, wherein the first n-type host comprises a triazene substituent or a pyrimidine substituent.

19. The light emitting device according to claim 1, wherein the second n-type host comprises a compound of Formula 2: 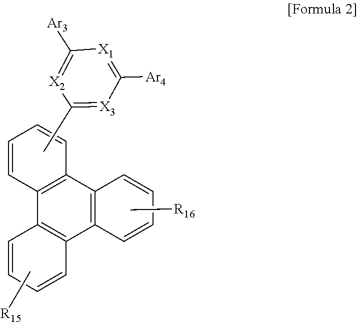
wherein:
X₁ to X₃ are each selected from nitrogen (N) and C—R, and further wherein at least two of X₁ to X₃ are nitrogen (N);
R, R₁₅, and R₁₆ are each independently selected from hydrogen, deuterium, halogen, cyano (CN), C1-C20 alkyl, C3-C20 cycloalkyl, substituted or unsubstituted C6-C30 aryl, and substituted or unsubstituted C5-C30 heteroaryl, and Ar₃ and Ar₄ are each independently selected from substituted or unsubstituted C6-C30 aryl, and substituted or unsubstituted C5-C30 heteroaryl.

20. A light emitting display device comprising:
a substrate including a plurality of subpixels;
a thin film transistor provided in each of the plurality of subpixels; and
the light emitting device according to claim 1, the light-emitting device being connected to the thin film transistor in the plurality of subpixels.
